(19) United States
(12) Patent Application Publication
(10) Pub. No.: US 2007/0058352 A1
(43) Pub. Date: Mar. 15, 2007

(54) PACKAGE STRUCTURE FOR AN INTERFACE CARD

(75) Inventor: Mu-Fu Lin, Hsin Tien (TW)

Correspondence Address: NIKOLAI & MERSEREAU, P.A., 900 SECOND AVENUE SOUTH, SUITE 820, MINNEAPOLIS, MN, 55402, US

(73) Assignee: D & C TECHNOLOGY CO., LTD., Hsin Tien (TW)

(21) Appl. No.: 11/162,483

(22) Filed: Sep. 12, 2005

(51) Int. Cl. H05K 1/14

(52) U.S. Cl. 361/740

(57) ABSTRACT

A package structure for an interface card comprises an upper cover, a lower cover, a frame, a connecting port, a rear extending seat, a rear extending cover and a printed circuit board. The upper cover is provide on its connecting side with a plurality of inserting members that extend vertically downward therefrom, the inserting members are spaced apart from one another by an interval and each is formed in the shape of an acute angle, in the frame is formed at least a groove for mating with the connecting side of the upper cover.

### BACKGROUND OF THE INVENTION

1. Field of the Invention

The present invention relates to an interface card, and more particularly to a package structure for an interface card.

2. Description of the Prior Art

All cards used on electronic or digital devices are generally called interface card, which include network interface card, memory card and so on. The interface card is usually encapsulated in a package, and the conventional package structures for these interface cards are similar and still have the following shortcomings:

1, the structure of the conventional package is complicated and not adapted for package process, which results in a lower production capacity and high production cost.

2, to overcome the abovementioned shortcoming, another package structure has been developed, in which, the interface card is produced by insert molding which is done in an automatic manner. This method can improve the production capacity, however, a new problem is that the stress and high temperature arose from the insert molding process will probably cause deformation of the metal portion and plastic frame of the interface card package.

The present invention has arisen to mitigate and/or obviate the afore-described disadvantages.

### SUMMARY OF THE INVENTION

The primary objective of the present invention is to provide a package structure for an interface card that is low cost and can be assembled quickly and easily.

The primary objective of the present invention is to provide a package structure for an interface card, wherein the structure of the interface card package is improved in structural strength and can be prevented from deformation during assembling process.

A package structure for an interface card in accordance with the present invention comprises an upper cover, a lower cover, a frame, a connecting port, a rear extending seat, a rear extending cover and a printed circuit board. the upper cover is provide on its connecting side with a plurality of inserting members that extend vertically downward therefrom, the inserting members are spaced apart from one another by an interval and each is formed in the shape of an acute angle, in the frame is formed at least a groove for mating with the connecting side of the upper cover.

The present invention will become more obvious from the following description when taken in connection with the accompanying drawings, which show, for purpose of illustrations only, the preferred embodiment in accordance with the present invention.

### BRIEF DESCRIPTION OF THE DRAWINGS

FIG. 1 is a perspective view of a package structure for an interface card in accordance with the present invention;

FIG. 2 is an exploded view of the package structure for an interface card in accordance with the present invention;

FIG. 3 is an illustrative view of showing the upper cover of the package structure in accordance with the present invention;

FIG. 4A shows the frame of the package structure in accordance with the present invention;

FIG. 4B is an amplified view of a part of FIG. 4A for showing the cavities formed in the bottom of the groove of the frame;

FIG. 5 is a cross sectional assembly view of showing a part of the package structure for an interface card in accordance with the present invention;

FIG. 6 is another cross sectional assembly view of showing a part of the package structure for an interface card in accordance with the present invention.

### DETAILED DESCRIPTION OF THE PREFERRED EMBODIMENT

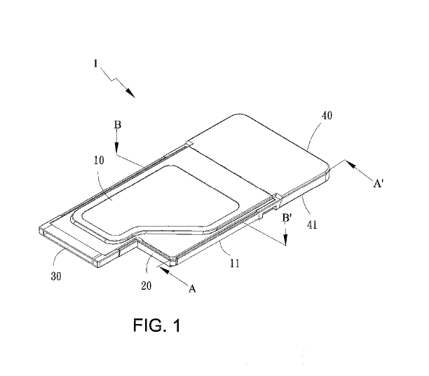

Referring to FIG. 1, a package structure for an interface card in accordance with the present invention is shown, in which the interface card 1, whose appearance is similar to the conventional interface card, comprises an upper cover 10, a lower cover 11, a frame 20, a connecting port 30, a rear extending seat 40, a rear extending cover 41 and a printed circuit board (PCB) 50 (not shown in FIG. 1).

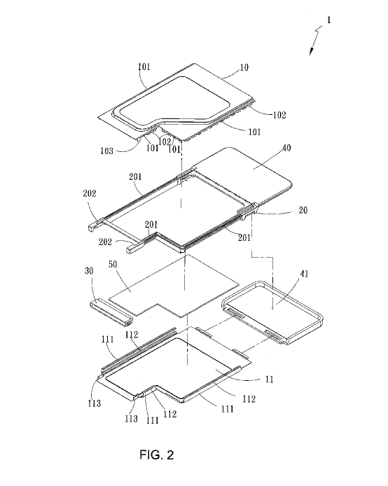

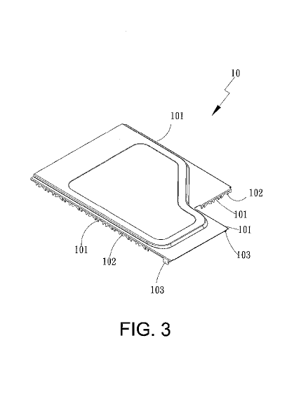

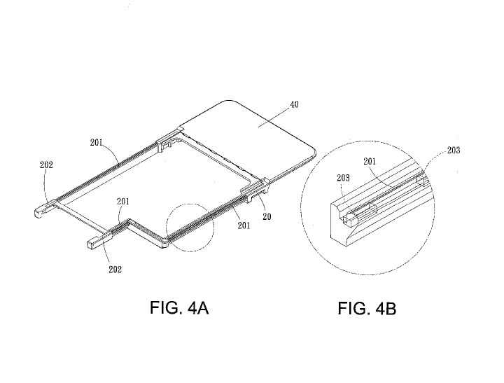

Referring to FIG. 2, the upper cover 10 of the interface card 1 is made of metal, on a connecting side 101 of the upper cover 10 are arranged a plurality of inserting members 102 vertically extended downward therefrom. The inserting members 102 are spaced apart from one another by an interval and each is formed in the shape of an acute angle. At either side of the front edge of the upper cover 10 is formed at least a retaining member 103 that is vertically extended downward therefrom, as shown in FIG. 3, which shows the upper cover from another angle. The lower cover 11 is also made of metal material, on the connecting side 111 of the lower cover 11 is arranged an elongated connecting member 112 that is a “[”-shaped in cross section and has certain flexibility. At either side of the front edge of the lower cover 11 is arranged a retaining member 113 that is vertically extended upward. The frame 20 is made of plastic material and is formed with a groove 201 for mating with the connecting side 101 of the upper cover 10. At either side of the front edge of the frame 20 is formed at least a locking recess 202 for mating with the retaining member 103 of the upper cover 10. With reference to FIGS. 4A and 4B, the groove 201 is shown in an amplified way. The connecting port 30 is a standardized component employed to connect the computer or digital products. The rear extending seat 40 is made of plastic material, so it can be connected to or integral with the rear portion of the frame 20, and then the rear extending seat 40 is covered with a rear cover 41.

The interface card 1 is assembled by pushing the inserting members 102 of the connecting side 101 of the upper cover 10 into the groove 201 of the frame 20, this can be done by special using special tools, and the details of how it is done are explained later. After the connecting side 101 of the upper cover 10 into the groove 201 of the frame 20, the retaining member 103 at both front sides of the upper cover 10 will locked into the locking recesses 202 of the frame 20 automatically. After this, the connecting port 30 is assembled to the PCB 50, and they are disposed at the front end and inside of the frame 20, respectively. Then, the connecting member 112 on the connecting side 111 of the lower cover 11 is engaged with the frame 20 in such a manner that the retaining member 113 at either side of the front edge of the lower cover is engaged in the retaining hole (not shown) formed in the lower surface of the connecting portion 30. Finally, the rear cover 41 is mounted on the rear extending seat 40 and engaged with the rear end of the lower cover 11.

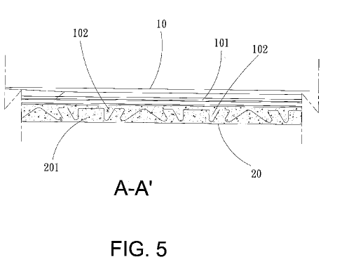

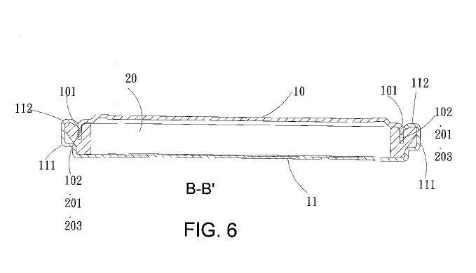

For better understanding of how the interface card 1 is assembled, reference should be made to FIGS. 3, 4A and 4B, the inserting members 102 on the connecting side 101 of the upper cover 10 are pushed into the groove 201 of the frame 20 and then are encapsulated therein by using any means, such as by using supersonic welding technology, as shown in FIGS. 5 and 6. And then the connecting member 112 on the connecting side 111 of the lower cover 11 is engaged with the corresponding edge of the frame 20, in this way, the interface card can be assembled quickly and easily.

In addition, in the bottom of the groove 201 of the frame 20 can be defined a plurality of locking cavities 203 for mating with the inserting members 102 of the connecting side 101 of the upper cover 10, so that the inserting members 102 of the upper cover 10 can be engaged in the groove 201 of the frame more closely.

While we have shown and described various embodiments in accordance with the present invention, it should be clear to those skilled in the art that further embodiments may be made without departing from the scope of the present invention.

What is claimed is:

1. A package structure for an interface card comprising an upper cover, a lower cover, a frame, a connecting port, a rear extending seat, a rear extending cover and a printed circuit board, wherein the upper cover is provide on its connecting side with a plurality of inserting members that extend vertically downward therefrom, the inserting members are spaced apart from one another by an interval and each is formed in the shape of an acute angle, in the frame is formed at least a groove for mating with the connecting side of the upper cover.

2. The package structure for an interface card as claimed in claim 1, wherein the inserting members on the connecting side of the upper cover are engaged in the groove of the frame and are encapsulated therein by any professional means.

3. The package structure for an interface card as claimed in claim 1, wherein a plurality of locking cavities are formed in a bottom of the groove of the frame for mating with the inserting members of the connecting side of the upper cover, so that the inserting members of the upper cover can be engaged in the groove of the frame more closely.

4. The package structure for an interface card as claimed in claim 1, wherein the upper cover is made of metal.

5. The package structure for an interface card as claimed in claim 1, wherein the frame is made of plastic.

6. The package structure for an interface card as claimed in claim 1, wherein at least a retaining member is arranged at either side of a front edge of the upper cover and vertically extends downward therefrom.

7. The package structure for an interface card as claimed in claim 1, wherein at least a locking recess is formed at either side of a front edge of the frame for mating with the retaining member of the upper cover.
